(19) United States
(12) Patent Application Publication
(10) Pub. No.: US 2021/0249359 A1
(43) Pub. Date: Aug. 12, 2021

(54) PACKAGE WITH INTEGRATED STRUCTURE

(71) Applicant: QUALCOMM Incorporated, San Diego, CA (US)

(72) Inventors: Aniket PATIL, San Diego, CA (US); Bohan YAN, San Diego, CA (US); Hong Bok WE, San Diego, CA (US)

(21) Appl. No.: 16/783,768

(22) Filed: Feb. 6, 2020

(51) Int. Cl. H01L 23/552; H01L 23/367; H01L 23/31; H01L 23/498; H01L 23/532; H01L 23/538; H01L 21/50

(52) U.S. Cl. CPC H01L 23/552; H01L 23/367; H01L 23/31; H01L 21/50; H01L 23/53228; H01L 23/5385; H01L 23/49816

(57) ABSTRACT

Examples herein include better heat transfer from application processor(s) and power management system without affecting the EMI performance. In one example, a thermal solution structure improves thermal performance of a modular system with better EMI shielding with the addition of heat conduction pillars from the substrate metal layer to TIM material, which thereafter connects to a heat pipe. The pillar transfers heat from substrate to heat pipe and connects physically to a global ground reference net of the IC package and eventually to a system motherboard while the pillar shields components inside the array/ring. This gives both a thermal and EMI shield solution in a single structure.

### FIELD OF DISCLOSURE

This disclosure relates generally to integrated circuit (IC) packages, and more specifically, but not exclusively, to electromagnetic interference (EMI) and thermal protection for IC packages.

### BACKGROUND

Increasing application processor operating speed, capacity and functionality requires bigger silicon and consequently bigger packaging solution footprint that mounts on board. However, there is a limitation to increasing packaging solution size because of the space limitation of printed circuit board. This led to the implementation of compact structure requirements. Higher operating speeds and compact structure requirements causes application processing die to consume and produce more power, consequently generating more heat. Thus, a better solution to dissipate this heat needs to be implemented compared to conventional/traditional solution. At same time, higher speed operations require EMI shielding of one component from other. As the integrated structures are getting more compact, components are getting closer to each other; consequently EMI shielding requirements are getting more important. Thus, a better solution to provide appropriate EMI shielding along with a better thermal solution is required.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, an integrated circuit package comprises: a substrate; a die attached to a first side of the substrate; a thermal interface layer on a first side of the die opposite the substrate; a heat spreader attached to the thermal interface layer; and a plurality of thermally conductive connections attached to the first side of the substrate proximate to the die and attached to the thermal interface layer, the plurality of thermally conductive connections at least partial surrounding the die between the substrate and the thermal interface layer and located within a perimeter of the heat spreader.

In another aspect, an integrated circuit package comprises: a substrate; a die attached to a first side of the substrate; a thermal interface layer on a first side of the die opposite the substrate; means for heat exchange attached to the thermal interface layer; and means for connection attached to the first side of the substrate proximate to the die and attached to the thermal interface layer, the means for connection at least partial surrounding the die between the substrate and the thermal interface layer and located within a perimeter of the means for heat exchange.

In still another aspect, a method for manufacturing an integrated circuit package comprises: providing a substrate; attaching a die to a first side of the substrate; attaching a plurality of thermally conductive connections to the first side of the substrate proximate to the die, the plurality of thermally conductive connections at least partial surrounding the die; applying a thermal interface layer on a first side of the die opposite the substrate; and attaching a heat spreader to the thermal interface layer.

In still another aspect, A non-transitory computer-readable medium comprising instructions that when executed by a processor cause the processor to perform a method comprising: providing a substrate; attaching a die to a first side of the substrate; attaching a plurality of thermally conductive connections to the first side of the substrate proximate to the die, the plurality of thermally conductive connections at least partial surrounding the die; applying a thermal interface layer on a first side of the die opposite the substrate; and attaching a heat spreader to the thermal interface layer.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIGS. 1A-C illustrate an exemplary integrated circuit package in accordance with some examples of the disclosure;

FIGS. 2A-C illustrate another exemplary integrated circuit package in accordance with some examples of the disclosure;

FIGS. 3A-G illustrates an exemplary method for manufacturing an integrated circuit package in accordance with some examples of the disclosure;

FIG. 4 illustrates another exemplary method for manufacturing an integrated circuit package in accordance with some examples of the disclosure;

FIG. 5 illustrates an exemplary mobile device in accordance with some examples of the disclosure; and

FIG. 6 illustrates various electronic devices that may be integrated with any of the aforementioned integrated device, semiconductor device, integrated circuit, die, interposer, package or package-on-package (PoP) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. For instance, examples herein include better heat transfer from application processor(s) and power management system without affecting the EMI performance. In one example, a thermal solution structure improves thermal performance of a modular system with better EMI shielding with the addition of heat conduction pillars from the substrate metal layer to TIM material, which thereafter connects to a heat pipe. The pillar transfers heat from substrate to heat pipe and connects physically to a global ground reference net of the IC package and eventually to a system motherboard while the pillar shields components inside the array/ring. This gives both a thermal and EMI shield solution in a single structure.

Examples herein provide many benefits over conventional approaches to thermal and EMI protection, such as electrically and thermally conductive connections (e.g., electrically and thermally conductive materials such as metals and metal alloys including copper) that may be approximately 150 microns in height and only connect to a single substrate (as opposed to between two substrates) allowing a smaller z height to the package in light of restrictions on stack or package height caused by smaller device profiles (e.g., a mobile phone with a stack height requirement of 50 microns) that may incorporate the integrated circuit packages. In addition, examples herein provide better heat flow without a negative impact on the EMI protection. Also, using electrically and thermally conductive connections surrounding the die(s) allows better EMI and thermal protection.

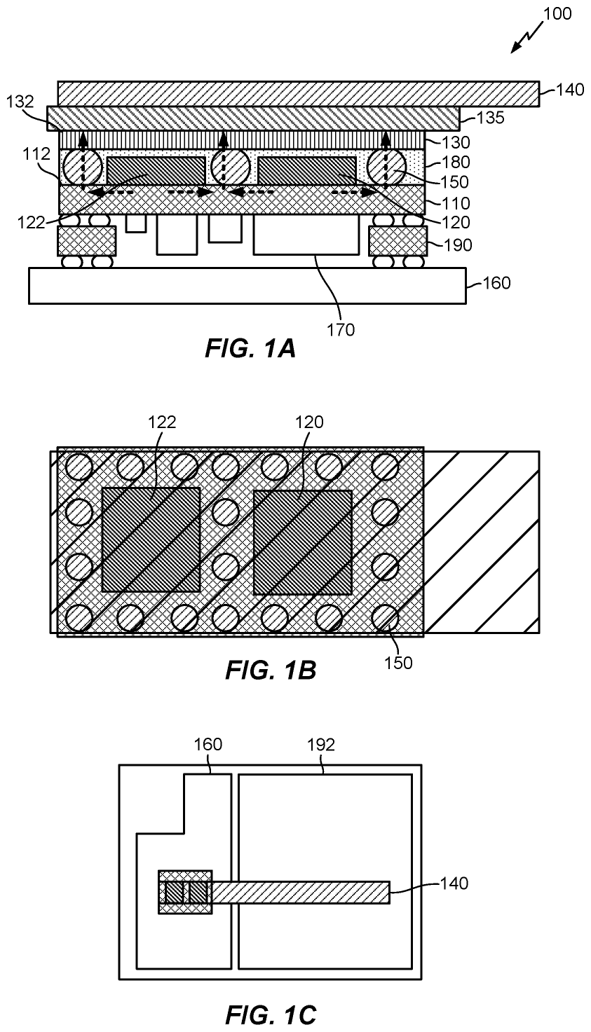

FIGS. 1A-C illustrate an exemplary integrated circuit package in accordance with some examples of the disclosure. As shown in FIG. 1A, an integrated circuit package 100 may include a package substrate 110, a first die 120 and a second die 122 attached to a first side 112 of the substrate 110; a thermal interface layer 130 on a first side of the first die 120 and the second die 122 opposite the substrate 110; a copper plate 135 attached to the thermal interface layer 130 on a first side 132 opposite the first die 120 and the second die 122; a heat spreader 140 attached to the copper plate 135; and a plurality of thermally conductive connections 150 (e.g., electrically and thermally conductive materials such as metals and metal alloys including copper) attached to the first side 112 of the substrate 110 proximate to the first die 120 and the second die 122 and attached to the thermal interface layer 140 while at least partial surrounding the first die 120 and the second die 122 between the substrate 110 and the thermal interface layer 140 and located within a perimeter of the heat spreader 140. While a copper plate 135 is shown, it should be understood that the copper plate 135 may be optional and the heat spreader 140 may be directly attached to the thermal interface layer 130.

The integrated circuit package 100 may also include a printed circuit board 160 attached to the substrate 110 on a second side of the substrate 110 opposite the first side 112 of the substrate 110, a plurality of surface mounted devices 170 attached to the second side of the substrate 110, a mold compound 180 encapsulating the plurality of thermally conductive connections and the die, interposers 190 between substrate 110 and the printed circuit board 160, and a ground coupled to the plurality of thermally conductive connections 150 for EMI protection that may be routed through the substrate 110 and the interposers 190 to the printed circuit board 160. As shown, the plurality of thermally conductive connections 150 are ball but it should be understood that they may be other shapes such as pillars and may be other materials that conduct heat and electrical signals. In addition, while shown as a heat pipe, the heat spreader 140 may be a heat sink or similar structures. Furthermore, while two die are shown, it should be understood that more or less than two die may be used.

FIG. 1B is a semi-transparent top down view of the integrated circuit package 100. As shown in FIG. 1B, the plurality of thermally conductive connections 150 surround the first die 120 and the second die 122 on all sides between the substrate 110 and the thermal interface layer 130. This may allow the plurality of thermally conductive connections to transfer more heat as well as shield the dies from outside EMI influences, EMI influences from each other, and EMI influences of other devices, such as the surface mounted devices 170. In addition, while two die are shown, it should be understood that more or less than two die may be used. Also, while the first die 120 and the second die 122 are completely surround on the sides by the plurality of thermally conductive connections 150, the plurality of thermally conductive connections may be completely or only partially enclose one or both die.

FIG. 1C is a semi-transparent top down view that includes a battery 192, such as in a mobile device. As shown, the heat spreader 140 extends past the printed circuit board 160 to transfer heat away from the dies.

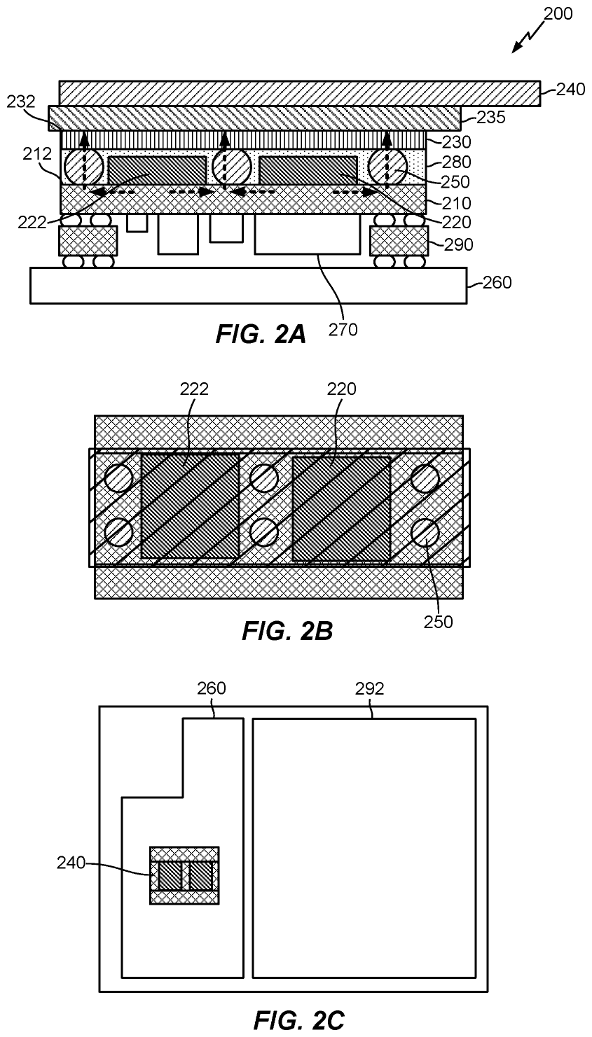

FIGS. 2A-C illustrate another exemplary integrated circuit package in accordance with some examples of the disclosure. As shown in FIG. 2A, an integrated circuit package 200 may include a package substrate 210, a first die 220 and a second die 222 attached to a first side 222 of the substrate 210; a thermal interface layer 230 on a first side of the first die 220 and the second die 222 opposite the substrate 210; a copper plate 235 attached to the thermal interface layer 230 on a first side 232 opposite the first die 220 and the second die 222; a heat spreader 240 attached to the copper plate 235; and a plurality of thermally conductive connections 250 attached to the first side 222 of the substrate 210 proximate to the first die 220 and the second die 222 and attached to the thermal interface layer 240 while at least partial surrounding the first die 220 and the second die 222 between the substrate 210 and the thermal interface layer 240 and located within a perimeter of the heat spreader 240. While a copper plate 235 is shown, it should be understood that the copper plate 235 may be optional and the heat spreader 240 may be directly attached to the thermal interface layer 230.

The integrated circuit package 200 may also include a printed circuit board 260 attached to the substrate 210 on a second side of the substrate 210 opposite the first side 222 of the substrate 220, a plurality of surface mounted devices 270 attached to the second side of the substrate 210, a mold compound 280 encapsulating the plurality of thermally conductive connections and the die, interposers 290 between substrate 210 and the printed circuit board 260, and a ground coupled to the plurality of thermally conductive connections 250 for EMI protection that may be routed through the substrate 210 and the interposers 290 to the printed circuit board 260. As shown, the plurality of thermally conductive connections 250 are ball but it should be understood that they may be other shapes such as pillars and may be other materials that conduct heat and electrical signals. In addition, while shown as a heat sink, the heat spreader 240 may be a heat pipe or similar structures. Furthermore, while two die are shown, it should be understood that more or less than two die may be used.

FIG. 2B is a semi-transparent top down view of the integrated circuit package 200. As shown in FIG. 2B, the plurality of thermally conductive connections 250 surround the first die 220 and the second die 222 on all sides between the substrate 210 and the thermal interface layer 230. This may allow the plurality of thermally conductive connections to transfer more heat as well as shield the dies from outside EMI influences, EMI influences from each other, and EMI influences of other devices, such as the surface mounted devices 270. In addition, while two die are shown, it should be understood that more or less than two die may be used. Also, while the first die 220 and the second die 222 are completely surround on the sides by the plurality of thermally conductive connections 250, the plurality of thermally conductive connections may be completely or only partially enclose one or both die.

FIG. 2C is a semi-transparent top down view that includes a battery 292, such as in a mobile device. As shown, the heat spreader 240 extends past the printed circuit board 260 to transfer heat away from the dies.

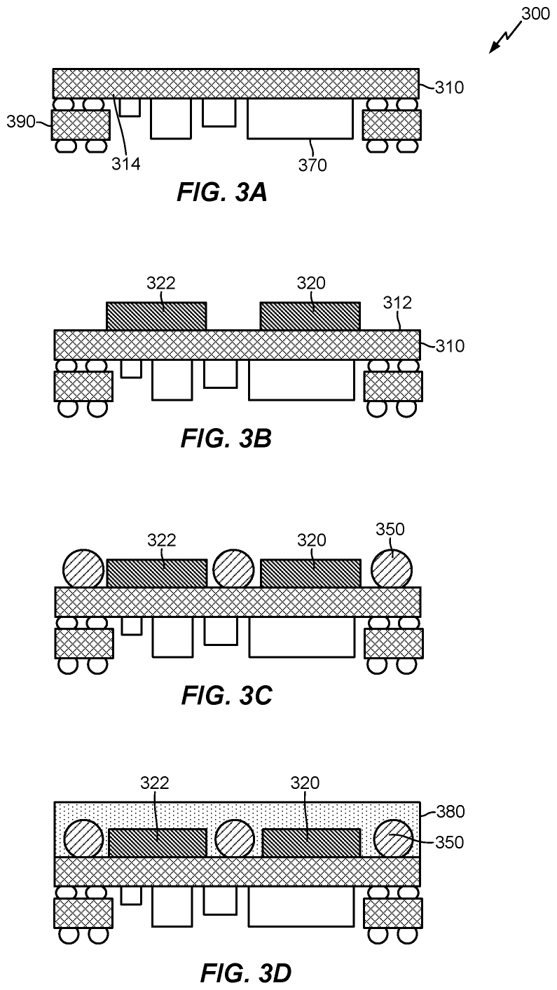

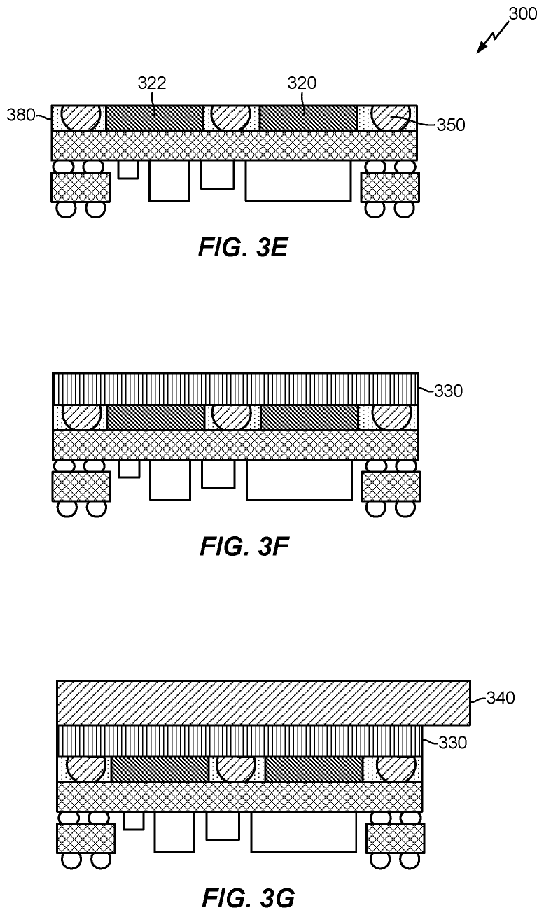

FIGS. 3A-G illustrate an exemplary method for manufacturing an integrated circuit package in accordance with some examples of the disclosure. As shown in FIG. 3A, a partial method 300 may begin with providing a substrate 310, attaching a plurality of surface mounted devices 370 on a second side 314 of the substrate 310, and attaching interposers 390 proximate the surface mounted devices 370 on the second side 314 of the substrate 310. As shown in FIG. 3B, the partial method 300 may continue with attaching a first die 320 and a second die 322 on a first side 312 of the substrate 310. As shown in FIG. 3C, the partial method 300 may continue with attaching a plurality of thermally conductive connections 350 (e.g., ball attach/drop or pillar plating) at least partially surrounding the first die 320 and the second 322 on the sides and between each die. As shown in FIG. 3D, the partial method 300 may continue with applying a mold compound 380 to encapsulate the plurality of thermally conductive connections 350, the first die 320, and the second die 322.

As shown in FIG. 3E, the partial method 300 may continue with back grinding the mold compound 380 to desired thickness to reveal the plurality of thermally conductive connections 350 and, optionally, a backside of the first die 320 and the second die 322. Back grinding all features to the same height may allow a direct connection between each feature to the thermal interface layer 330 that may allow better heat transfer through the thermal interface layer 330 to the heat spreader 340. As shown in FIG. 3F, the partial method 300 may continue with applying the thermal interface 330 as shown. As shown in FIG. 3G, the partial method 300 may conclude with attaching the heat exchange 340 to the thermal interface layer 330. Optionally, the partial method 300 may include a copper plate (not shown) with the heat spreader 340 on the thermal interface layer 330 to increase the capacity of the heat spreader 340 (e.g., copper plate 135, copper plate 235).

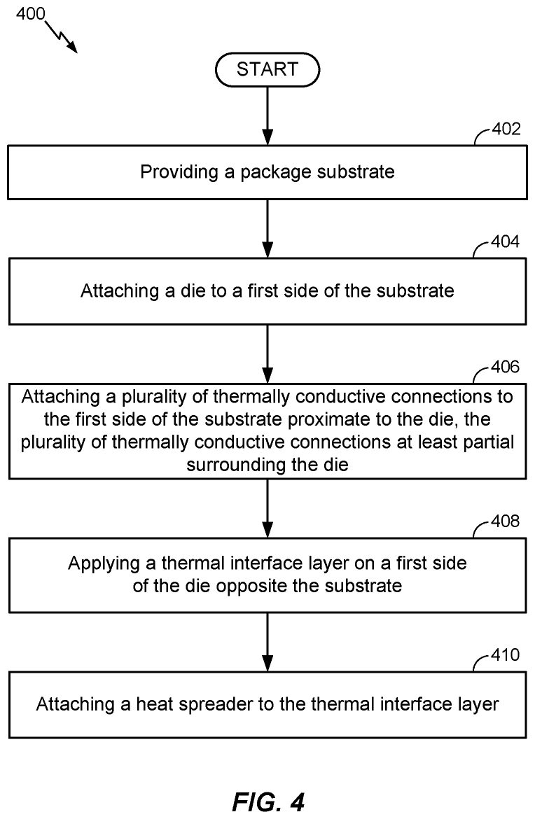

FIG. 4 illustrates another exemplary method for manufacturing an integrated circuit package in accordance with some examples of the disclosure. As shown in FIG. 4, a partial method 400 for manufacturing an integrated circuit package 400 may being in block 402 with providing a package substrate. The partial method 400 may continue in block 404 with attaching a die to a first side of the substrate. The partial method 400 may continue in block 406 with attaching a plurality of thermally conductive connections to the first side of the substrate proximate to the die, the plurality of thermally conductive connections at least partial surrounding the die. The partial method 400 may continue in block 408 with applying a thermal interface layer on a first side of the die opposite the substrate. The partial method 400 may conclude in block 410 with attaching a heat spreader to the thermal interface layer.

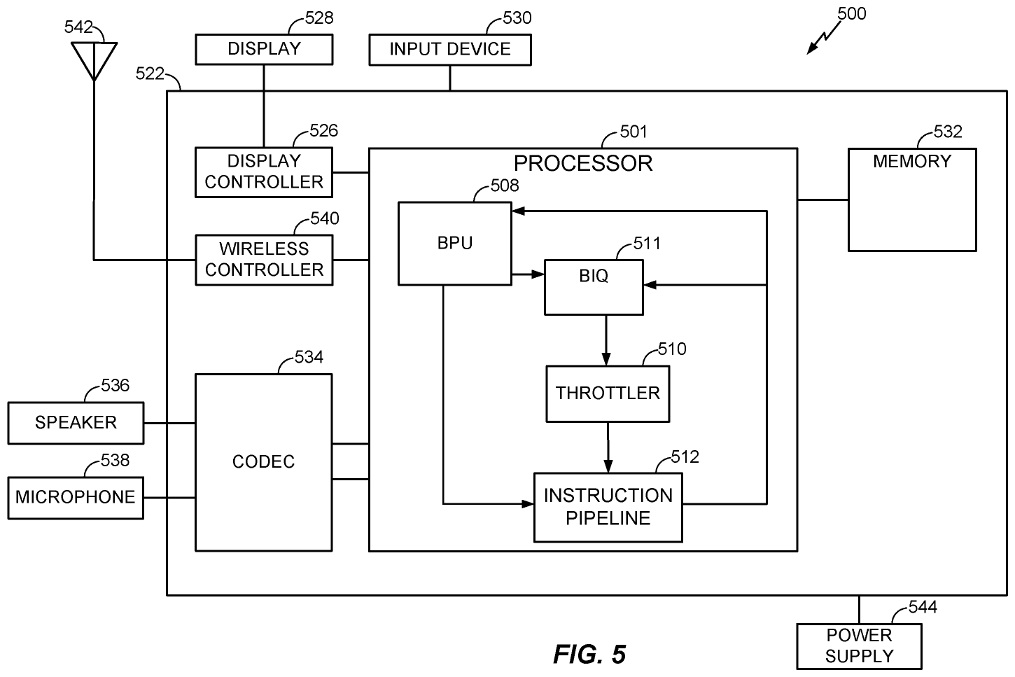

FIG. 5 illustrates an exemplary mobile device in accordance with some examples of the disclosure. Referring now to FIG. 5, a block diagram of a mobile device that is configured according to exemplary aspects is depicted and generally designated 500. In some aspects, mobile device 500 may be configured as a wireless communication device. As shown, mobile device 500 includes processor 501, which may be configured to implement the methods described herein in some aspects. Processor 501 is shown to comprise instruction pipeline 512, buffer processing unit (BPU) 508, branch instruction queue (BIQ) 511, and throttler 510 as is well known in the art. Other well-known details (e.g., counters, entries, confidence fields, weighted sum, comparator, etc.) of these blocks have been omitted from this view of processor 501 for the sake of clarity.

Processor 501 may be communicatively coupled to memory 532 over a link, which may be a die-to-die or chip-to-chip link. Mobile device 500 also include display 528 and display controller 526, with display controller 526 coupled to processor 501 and to display 528.

In some aspects, FIG. 5 may include coder/decoder (CODEC) 534 (e.g., an audio and/or voice CODEC) coupled to processor 501; speaker 536 and microphone 538 coupled to CODEC 534; and wireless controller 540 (which may include a modem) coupled to wireless antenna 542 and to processor 501.

In a particular aspect, where one or more of the above-mentioned blocks are present, processor 501, display controller 526, memory 532, CODEC 534, and wireless controller 540 can be included in a system-in-package or system-on-chip device 522. Input device 530 (e.g., physical or virtual keyboard), power supply 544 (e.g., battery), display 528, input device 530, speaker 536, microphone 538, wireless antenna 542, and power supply 544 may be external to system-on-chip device 522 and may be coupled to a component of system-on-chip device 522, such as an interface or a controller.

It should be noted that although FIG. 5 depicts a mobile device, processor 501 and memory 532 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

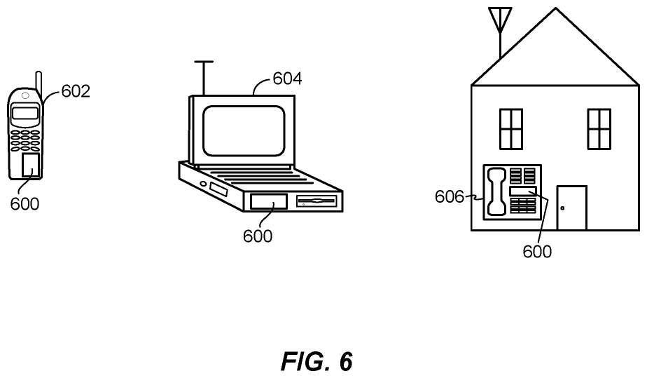

FIG. 6 illustrates various electronic devices that may be integrated with any of the aforementioned integrated device, semiconductor device, integrated circuit, die, interposer, package or package-on-package (PoP) in accordance with some examples of the disclosure. For example, a mobile phone device 602, a laptop computer device 604, and a fixed location terminal device 606 may include an integrated device 600 as described herein. The integrated device 600 may be, for example, any of the integrated circuits, dies, integrated devices, integrated device packages, integrated circuit devices, device packages, integrated circuit (IC) packages, package-on-package devices described herein. The devices 602, 604, 606 illustrated in FIG. 6 are merely exemplary. Other electronic devices may also feature the integrated device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device comprising means for performing the respective actions of this method. For example, in one aspect, an integrated circuit package may comprises: a package substrate (e.g., package substrate 110, package substrate 210); a die (e.g., die 120, die 122, die 220, die 222) attached to a first side of the substrate; a thermal interface layer (e.g., thermal interface layer 130, thermal interface layer 230) on a first side of the die opposite the substrate; means for heat exchange (e.g., heat spreader 140, heat spreader 240) attached to the thermal interface layer on a first side opposite the die; and means for connection (e.g., plurality of thermally conductive connections 150, plurality of thermally conductive connections 250) attached to the first side of the substrate proximate to the die and attached to the thermal interface layer, the means for connection at least partial surrounding the die between the substrate and the thermal interface layer and located within a perimeter of the means for heat exchange. It will be appreciated that the aforementioned aspects are merely provided as examples and the various aspects claimed are not limited to the specific references and/or illustrations cited as examples.

One or more of the components, processes, features, and/or functions illustrated in FIGS. 1-6 may be rearranged and/or combined into a single component, process, feature or function or incorporated in several components, processes, or functions. Additional elements, components, processes, and/or functions may also be added without departing from the disclosure. It should also be noted that FIGS. 1-6 and its corresponding description in the present disclosure is not limited to dies and/or ICs. In some implementations, FIGS. 1-6 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of the device, such as a die, is the part of the device that contains the active components of the device (e.g., transistors, resistors, capacitors, inductors, etc.), which perform the operation or function of the device. The backside of a device is the side of the device opposite the active side.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to an uplink/reverse or downlink/forward traffic channel.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

The various dies described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or other such configurations). Additionally, these sequence of actions described herein can be considered to be incorporated entirely within any form of computer-readable storage medium (transitory and non-transitory) having stored therein a corresponding set of computer instructions that upon execution would cause an associated processor to perform the functionality described herein. Thus, the various aspects of the disclosure may be incorporated in a number of different forms, all of which have been contemplated to be within the scope of the claimed subject matter. In addition, for each of the examples described herein, the corresponding form of any such examples may be described herein as, for example, “logic configured to” perform the described action.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. An integrated circuit package comprising:
a substrate;
a die attached to a first side of the substrate;
a thermal interface layer on a first side of the die opposite the substrate;
a heat spreader attached to the thermal interface layer; and
a plurality of thermally conductive connections attached to the first side of the substrate proximate to the die and attached to the thermal interface layer, the plurality of thermally conductive connections at least partial surrounding the die between the substrate and the thermal interface layer and located within a perimeter of the heat spreader.

2. The integrated circuit package of claim 1, further comprising a printed circuit board attached to the substrate on a second side of the substrate opposite the first side of the substrate.

3. The integrated circuit package of claim 1, further comprising a surface mounted device attached to the second side of the substrate.

4. The integrated circuit package of claim 1, further comprising a mold compound encapsulating the plurality of thermally conductive connections and the die.

5. The integrated circuit package of claim 1, wherein the plurality of thermally conductive connections surround the die on all sides between the substrate and the thermal interface layer.

6. The integrated circuit package of claim 1, wherein the plurality of thermally conductive connections are one of a copper pillar or a copper ball.

7. The integrated circuit package of claim 1, wherein the heat spreader is one of a heat sink or a heat pipe and comprises a copper plate directly attached to the thermal interface layer.

8. The integrated circuit package of claim 1, wherein the integrated circuit package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

9. An integrated circuit package comprising:
a substrate;
a die attached to a first side of the substrate;
a thermal interface layer on a first side of the die opposite the substrate;
means for heat exchange attached to the thermal interface layer; and
means for connection attached to the first side of the substrate proximate to the die and attached to the thermal interface layer, the means for connection at least partial surrounding the die between the substrate and the thermal interface layer and located within a perimeter of the means for heat exchange.

10. The integrated circuit package of claim 9, further comprising a printed circuit board attached to the substrate on a second side of the substrate opposite the first side of the substrate.

11. The integrated circuit package of claim 9, further comprising a surface mounted device attached to the second side of the substrate.

12. The integrated circuit package of claim 9, further comprising a mold compound encapsulating the means for connection and the die.

13. The integrated circuit package of claim 9, wherein the means for connection surrounds the die on all sides between the substrate and the thermal interface layer.

14. The integrated circuit package of claim 9, wherein the means for connection is one of a pillar or a ball.

15. The integrated circuit package of claim 9, wherein the means for heat exchange is one of a heat sink or a heat pipe and comprises a copper plate directly attached to the thermal interface layer.

16. The integrated circuit package of claim 9, wherein the integrated circuit package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

17. A method for manufacturing an integrated circuit package, the method comprising:
providing a substrate;
attaching a die to a first side of the substrate;
attaching a plurality of thermally conductive connections to the first side of the substrate proximate to the die, the plurality of thermally conductive connections at least partial surrounding the die;
applying a thermal interface layer on a first side of the die opposite the substrate; and
attaching a heat spreader to the thermal interface layer.

18. The method of claim 17, wherein the plurality of thermally conductive connections are attached to the thermal interface layer and located within a perimeter of the heat spreader.

19. The method of claim 17, further comprising attaching a printed circuit board to the substrate on a second side of the substrate opposite the first side of the substrate.

20. The method of claim 17, further comprising attaching a surface mounted device to the second side of the substrate.

21. The method of claim 17, further comprising applying a mold compound to encapsulate the plurality of thermally conductive connections and the die.

22. The method of claim 17, wherein the plurality of thermally conductive connections surround the die on all sides between the substrate and the thermal interface layer.

23. The method of claim 17, wherein the plurality of thermally conductive connections are one of a copper pillar or a copper ball.

24. The method of claim 17, wherein the heat spreader is one of a heat sink or a heat pipe and comprises a copper plate directly attached to the thermal interface layer.

25. The method of claim 17, further comprising incorporating the integrated circuit package into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

26. A non-transitory computer-readable medium comprising instructions that when executed by a processor cause the processor to perform a method comprising:
providing a substrate;
attaching a die to a first side of the substrate;
attaching a plurality of thermally conductive connections to the first side of the substrate proximate to the die, the plurality of thermally conductive connections at least partial surrounding the die;
applying a thermal interface layer on a first side of the die opposite the substrate; and
attaching a heat spreader to the thermal interface layer.

27. The non-transitory computer-readable medium of claim 26, wherein the plurality of thermally conductive connections are attached to the thermal interface layer and located within a perimeter of the heat spreader.

28. The non-transitory computer-readable medium of claim 26, wherein the method further comprises attaching a printed circuit board to the substrate on a second side of the substrate opposite the first side of the substrate.

29. The non-transitory computer-readable medium of claim 26, wherein the method further comprises attaching a surface mounted device to the second side of the substrate.

30. The non-transitory computer-readable medium of claim 26, wherein the method further comprises applying a mold compound to encapsulate the plurality of thermally conductive connections and the die.
